(19) United States
(12) Patent Application Publication
(10) Pub. No.: US 2026/0082648 A1
(43) Pub. Date: Mar. 19, 2026

(54) SEMICONDUCTOR DEVICE

(71) Applicant: Samsung Electronics Co., Ltd., Suwon-si (KR)

(72) Inventors: Wookhyun Kwon, Suwon-si (KR); Jina Kim, Suwon-si (KR); Younggwon Kim, Suwon-si (KR); Myunggil Kang, Suwon si (KR); Jongpil Kim, Suwon si (KR); Yunyeong Yi, Suwon-si (KR); Byounghak Hong, Suwon-si (KR)

(21) Appl. No.: 19/091,045

(22) Filed: Mar. 26, 2025

(30) Foreign Application Priority Data
Sep. 13, 2024 (KR) 10-2024-0125850

(51) Int. Cl. H10D 62/13; H10D 30/00; H10D 30/01; H10D 62/10; H10D 64/23; H10D 64/27; H10D 84/01; H10D 84/83

(52) U.S. Cl. CPC H10D 62/151; H10D 30/506; H10D 62/121; H10D 64/256; H10D 64/516; H10D 84/832; H10D 30/0194; H10D 84/013; H10D 84/0147

(57) ABSTRACT

A semiconductor device includes a gate structure; a first source/drain region and a second source/drain region; a plurality of channel layers, wherein the plurality of channel layers includes a lowermost channel layer, an uppermost channel layer, and a first intermediate channel layer; and a contact plug, wherein each of the first source/drain region and the second source/drain region includes a plurality of protrusions including an uppermost protrusion, a lowermost protrusion, and a first intermediate protrusion, and wherein a distance between the uppermost protrusion of the first source/drain region and the uppermost protrusion of the second source/drain region and a distance between the lowermost protrusion of the first source/drain region and a lowermost protrusion of the second source/drain region are each less than a distance between the first intermediate protrusion of the first source/drain region and the first intermediate protrusion of the second source/drain region.

### CROSS-REFERENCE TO RELATED APPLICATION(S)

This application claims benefit of priority to Korean Patent Application No. 10-2024-0125850 filed on Sep. 13, 2024, in the Korean Intellectual Property Office, the disclosure of which is incorporated herein by reference in its entirety.

### BACKGROUND

Example embodiments of the present disclosure relate to a semiconductor device.

As demand for high performance, high speed, and/or multifunctionality of a semiconductor device has increased, integration density of a semiconductor device has increased. In manufacturing a semiconductor device having fine patterns corresponding to the trend toward high integration density of a semiconductor device, it may be necessary to implement patterns having a fine width or a fine spacing. Also, in order to overcome limitations in operating properties due to reduction in size of a planar MOSFET (metal oxide semiconductor FET), an effort have been made to develop a semiconductor device including transistors with channels having a three-dimensional structure.

### SUMMARY

An example embodiment of the present disclosure is to provide a semiconductor device having improved integration density and reliability.

According to an example embodiment of the present disclosure, a semiconductor device includes a gate structure extending in a first direction; a first source/drain region on a first side of the gate structure and a second source/drain region on second side of the gate structure opposing the first side spaced apart from each other in a second direction perpendicular to the first direction; a plurality of channel layers, each of the channel layers surrounded by the gate structure and located between the first and second source/drain regions, and spaced apart from each other in a vertical direction, wherein the plurality of channel layers include a lowermost channel layer, an uppermost channel layer, and a first intermediate channel layer between the lowermost channel layer and the lowermost channel layer; and a contact plug electrically connected to the first source/drain region, wherein each of the first source/drain region and the second source/drain region includes a plurality of protrusions including an uppermost protrusion connected to the uppermost channel layer below the uppermost channel layer and protruding in a direction toward the gate structure, a lowermost protrusion connected to the lowermost channel layer below the lowermost channel layer and protruding in the direction toward the gate structure, and a first intermediate protrusion connected to the first intermediate channel layer below the first intermediate channel layer and protruding in the direction toward the gate structure, and wherein a distance between the uppermost protrusion of the first source/drain region and the uppermost protrusion of the second source/drain region in the second direction and a distance between the lowermost protrusion of the first source/drain region and a lowermost protrusion of the second source/drain region in the second direction are each less than a distance between the first intermediate protrusion of the first source/drain region and the first intermediate protrusion of the second source/drain region in the second direction.

According to an example embodiment of the present disclosure, a semiconductor device includes a gate structure extending lengthwise in a first direction; a plurality of channel layers each of the channel layers surrounded by the gate structure, and the plurality of channel layers including an uppermost channel layer, a first intermediate channel layer, and a lowermost channel layer spaced apart from each other downwardly in order; and a source/drain region on a side of the gate structure and connected to the plurality of channel layers, wherein the source/drain region includes a plurality of protrusions including an uppermost protrusion protruding in a first horizontal direction toward the gate structure between the uppermost channel layer and the first intermediate channel layer, a first intermediate protrusion protruding in the first horizontal direction toward the gate structure between the first intermediate channel layer and the lowermost channel layer, and a lowermost protrusion protruding in the first horizontal direction toward the gate structure below the lowermost channel layer, and wherein a first maximum width in the first horizontal direction of a first portion including the uppermost protrusion of the source/drain region and a second maximum width in the first horizontal direction of a second portion including the lowermost protrusion of the source/drain region are each greater than a third maximum width in the first horizontal direction of a third portion including the first intermediate protrusion of the source/drain region.

According to an example embodiment of the present disclosure, a semiconductor device includes a gate structure extending in a first direction; a plurality of channel layers, each of the channel layers surrounded by the gate structure and including first, second, third, and fourth channel layers disposed downwardly in order; a source/drain region on a side of the gate structure and connected to the plurality of channel layers; and a contact plug electrically connected to the source/drain region, wherein the gate structure includes a first gate portion positioned between the first channel layer and the second channel layer, a second gate portion positioned between the second channel layer and the third channel layer, a third gate portion positioned between the third channel layer and the fourth channel layer, and a fourth gate portion positioned below the fourth channel layer, wherein a first gate width of the first gate portion is less than a second gate width of the second gate portion, and wherein a fourth gate width of the fourth gate portion is less than a third gate width of the third gate portion.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example embodiments of the present disclosure;

FIG. 2A is a cross-sectional diagram illustrating a semiconductor device according to example embodiments of the present disclosure;

FIG. 2B is an enlarged diagram illustrating a portion of a semiconductor device according to example embodiments of the present disclosure;

FIG. 3A is a cross-sectional diagram illustrating a semiconductor device according to example embodiments of the present disclosure;

FIG. 3B is an enlarged diagram illustrating a portion of a semiconductor device according to example embodiments of the present disclosure;

FIG. 4A is cross-sectional diagrams illustrating a semiconductor device according to example embodiments of the present disclosure;

FIG. 4B is an enlarged diagram illustrating a portion of a semiconductor device according to example embodiments of the present disclosure;

FIG. 5 is cross-sectional diagrams illustrating a semiconductor device according to example embodiments of the present disclosure;

FIGS. 6, 7, 8, 9A, 10A, 11, 12, 13A, and 14A are cross-sectional diagrams illustrating a method of manufacturing a semiconductor device according to example embodiments of the present disclosure; and

FIGS. 9B, 10B, 13B, and 14B are enlarged diagrams illustrating processes of a method of manufacturing a semiconductor device in order according to example embodiments of the present disclosure.

### DETAILED DESCRIPTION

Hereinafter, embodiments of the present disclosure will be described more fully hereinafter as follows with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

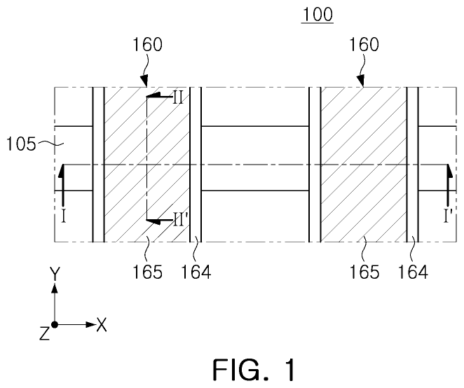

FIG. 1 is a plan diagram illustrating a portion of a semiconductor device according to example embodiments. For ease of description, FIG. 1 only illustrates a portion of components of a semiconductor device. Like all the semiconductor devices disclosed herein, the semiconductor memory device may be a semiconductor chip. Such a semiconductor chip may be a semiconductor device singulated from (e.g., cut from) a wafer (which wafer may be formed with one base substrate (e.g., a bulk silicon substrate, a bulk germanium substrate, silicon on insulator (SOI), etc.), e.g., or formed with a combination of several component wafers each having a corresponding base substrate).

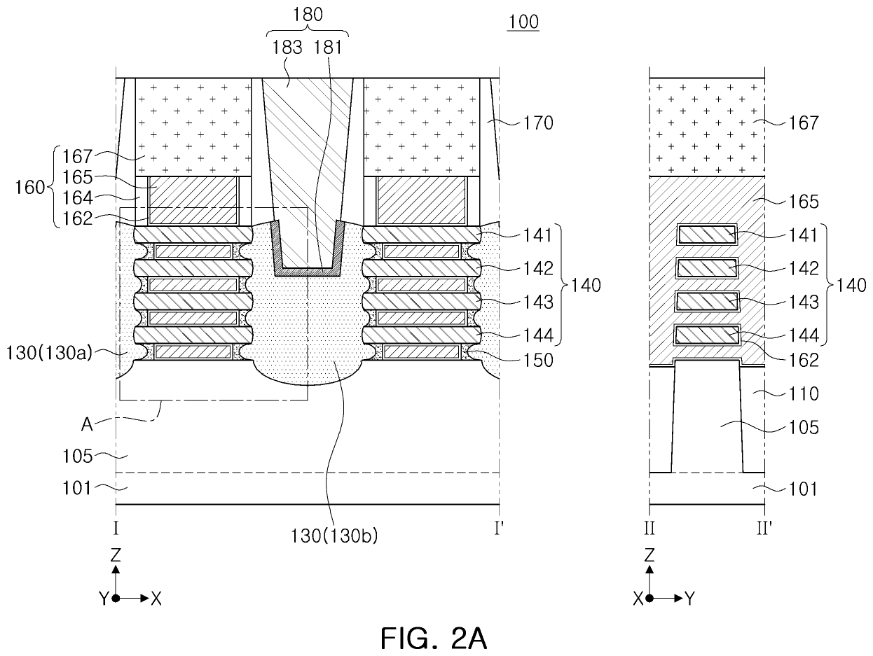

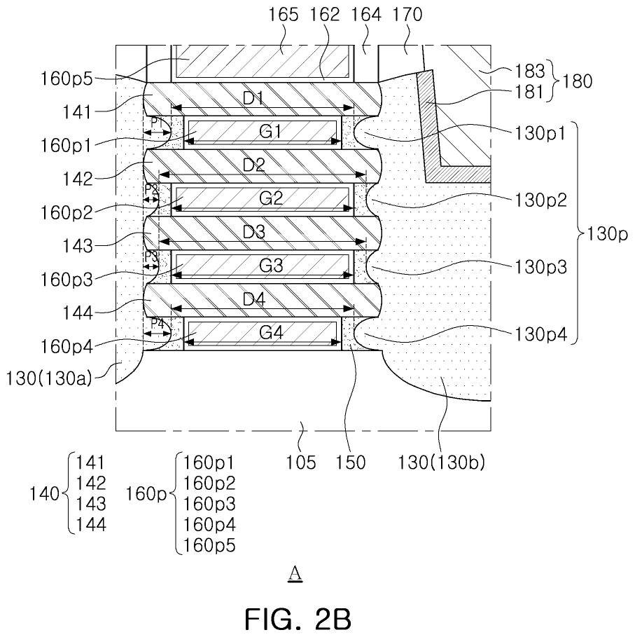

FIG. 2A is a cross-sectional diagram illustrating a portion of a semiconductor device according to example embodiments, taken along lines I-I′ and II-II′ of FIG. 1.

FIG. 2B is an enlarged diagram illustrating a portion of a semiconductor device according to example embodiments, illustrating region “A” in FIG. 2A.

Referring to FIGS. 1 to 2B, a semiconductor device 100 may include a substrate 101 including an active region 105, channel structures 140 including first to fourth channel layers 141, 142, 143, and 144 disposed apart from each other on the active region 105, gate structures 160 extending across and intersecting the active region 105 and each including a gate electrode 165, source/drain regions 130 connected to the channel structures 140, internal spacers 150 disposed between the gate structures 160 and the source/drain regions 130 below each of the channel layers 141, 142, 143, and 144, and contact plugs 180 connected to the source/drain regions 130. The semiconductor device 100 may further include a device isolation layer 110 and an interlayer insulating layer 170.

In the semiconductor device 100, the active region 105 may have a fin structure, and the gate electrode 165 may be disposed between the active region 105 and the channel structure 140, between the first to fourth channel layers 141, 142, 143, and 144 of the channel structure 140, and on the channel structure 140. Accordingly, the semiconductor device 100A may include transistors having a multi-bridge channel FET (MBCFET™) structure, which is a gate-all-around type field effect transistor.

The substrate 101 may have an upper surface extending laterally (e.g., a normal direction to the upper surface may be a Z-direction and the upper surface may extend in a X-direction and a Y-direction). The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include an active region 105 disposed in an upper portion of the substrate 101. The active region 105 may be defined by the device isolation layer 110 in the substrate 101 (e.g., the active region 105 may be a portion of the substrate 101 having a lateral boundary defined by the device isolation layer 110). The active region may extend lengthwise in one direction, for example, in the X-direction. The X-direction may be defined as the first direction or the second direction. Depending on the context of the description, the active region 105 may be described as a separate component from the substrate 101. The active region 105 may partially protrude above the device isolation layer 110, such that an upper surface of the active region 105 may be positioned at a level higher than a level of the upper surface of the device isolation layer 110. The active region 105 may be formed as a portion of the substrate 101, and may include an epitaxial layer grown from the substrate 101. However, the active region 105 may be partially recessed on opposing sides of the gate structure 160 such that recess regions may be formed, and at least a portion of a source/drain region 130 may be disposed in a recess region.

In example embodiments, the active region 105 may or may not include a well region including impurities. For example, in the case of a P-type transistor (pFET), the well region may include N-type impurities such as phosphorus (P), arsenic (As), or antimony (Sb), and in the case of an N-type transistor (nFET), the well region may include P-type impurities such as boron (B), gallium (Ga), or indium (In). The well region may be positioned at a predetermined depth from the upper surface of the active region 105, for example.

In example embodiments, at least a portion of the substrate 101 including the active region 105 may be removed and may be replaced with an insulating layer. The insulating layer replacing the removed substrate 101 may include, for example, at least one of oxide, nitride, and oxynitride.

The device isolation layer 110 may define the active region 105 in the substrate 101. The device isolation layer 110 may be formed, for example, by a shallow trench isolation (STI) process. The device isolation layer 110 may expose an upper surface of the active region 105, and may also expose a portion of the upper portion (e.g., an upper portion of the active region 105 may extend higher than an upper surface of the device isolation layer 110). In some example embodiments, the device isolation layer 110 may have a curved upper surface such that the device isolation layer 110 may have an increasing height relative to the substrate 101 as the device isolation layer 110 approaches the active region 105. The device isolation layer 110 may be formed of an insulating material. The device isolation layer 110 may be, for example, oxide, nitride, or a combination thereof.

The channel structures 140 may be disposed on the active region 105 in regions in which the active region 105 and the gate structures 160 intersect (e.g., overlap vertically). Each of the channel structures 140 may include a plurality of channel layers, such as first to fourth channel layers 141, 142, 143, and 144, that are spaced apart from each other in the Z-direction. The first to fourth channel layers 141, 142, 143, and 144 may be disposed downwardly in order, such that the first channel layer 141 positioned at the highest level may be referred to as an uppermost channel layer, and the fourth channel layer 144 positioned at the lowest level may be referred to as a lowermost channel layer. The second channel layer 142 and the third channel layer 143 may be referred to as an intermediate channel layer, a first intermediate channel layer, or a second intermediate channel layer. The channel structures 140 may be connected to the source/drain regions 130. The channel structures 140 may have a width in the X-direction equal to or similar to that of the gate structures 160, and a width in the Y-direction equal to or less than that of the active region 105. In a cross-sectional surface in the Y-direction such as that shown in the right hand side of FIG. 2A, a channel layer disposed in a lower portion among the first to fourth channel layers 141, 142, 143, and 144 may have a width equal to or greater than a channel layer disposed in an upper portion. The number of channel layers included in the channel structure 140 and the shape thereof may be varied in example embodiments. For example, a channel structure 140 may include three channel layers, two channel layers, or five or more channel layers. In some example embodiments, when the channel structure 140 includes three channel layers, the first channel layer 141 positioned at the highest level may be referred to as an uppermost channel layer, the second channel layer 142 may be referred to as an intermediate channel layer, and the third channel layer 143 positioned at the lowest level may be referred to as a lowermost channel layer.

The channel structures 140 may be formed of and/or include a semiconductor material, for example, silicon (Si), silicon germanium (SiGe), or germanium (Ge). The channel structures 140 may be formed of the same material as a material of the active region 105, for example. In some example embodiments, the channel structures 140 may also include an impurity region positioned adjacent to the source/drain regions 130.

The gate structures 160 may extend lengthwise in one direction, for example, the Y-direction, and intersect the active region 105 and the channel structures 140 on the active region 105 and the channel structures 140. The Y-direction may be defined as the second direction or the first direction. When the active region 105 is described as extending lengthwise in the first direction, the gate structures 160 may be described as extending lengthwise in the second direction intersecting the first direction. Conversely, when the gate structures 160 is described as extending lengthwise in the first direction, the active region 105 may be described as extending lengthwise in the second direction intersecting the first direction. In the active region 105 and/or the channel structures 140 intersecting the gate electrodes 165 of the gate structures 160, functional channel regions of the transistors may be formed. The first direction and the second direction may be referred to as the first horizontal direction and the second horizontal direction, respectively.

Each of the gate structures 160 may include a first gate portion 160p1 below the first channel layer 141 and above the second channel layer 142, a second gate portion 160p2 below the second channel layer 142 and above the third channel layer 143, a third gate portion 160p3 below the third channel layer 143 and above the fourth channel layer 144, a fourth gate portion 160p4 below the fourth channel layer 144 and above the active region 105, and a fifth gate portion 160p5 on the first channel layer 141. In some example embodiments, when the channel structure 140 includes three channel layers, the third gate portion 160p3 may be included in a lowermost portion of the gate structure 160. The first gate portion 160p1 may be positioned between the first channel layer 141 and the second channel layer 142 and may have a first gate width G1. The second gate portion 160p2 may be positioned between the second channel layer 142 and the third channel layer 143 and may have a second gate width G2. The third gate portion 160p3 may be positioned between the third channel layer 143 and the fourth channel layer 144 and may have a third gate width G3. The fourth gate portion 160p4 may be positioned between the fourth channel layer 144 and the active region 105 and may have a fourth gate width G4. When the gate structures 160 extend lengthwise, for example, in the Y-direction, the first to fourth gate widths G1, G2, G3, and G4 may be widths in the X-direction. In some example embodiments, when the active region 105 is removed, the fourth gate portion 160p4 may be positioned between the fourth channel layer 144 and the substrate 101 replaced with an insulating layer. The first to fourth gate portions 160p1, 160p2, 160p3, and 160p4 may have the same width or different widths depending on the shape of the source/drain regions 130. Each of the first gate width G1 and the fourth gate width G4 may be less than each of the second gate width G2 and the third gate width G3. A difference between the first gate width G1 and the fourth gate width G4 may be less than a difference between the first gate width G1 and the second gate width G2. A difference between the first gate width G1 and the fourth gate width G4 may be less than a difference between the first gate width G1 and the third gate width G3. A difference between the first gate width G1 and the fourth gate width G4 may be less than a difference between the fourth gate width G4 and the third gate width G3. A difference between the first gate width G1 and the fourth gate width G4 may be less than a difference between the fourth gate width G4 and the second gate width G2. In some example embodiments, the first gate width G1 and the fourth gate width G4 may be the same or substantially the same. In some example embodiments, the second gate width G2 and the third gate width G3 may be the same or substantially the same.

Each of the gate structures 160 may include a gate electrode 165, gate dielectric layers 162, gate spacer layers 164, and a gate capping layer 167.

The gate dielectric layers 162 may be disposed between the active region 105 and the gate electrode 165 and between the channel structure 140 and the gate electrode 165, and may be disposed to cover at least a portion of surfaces of the gate electrode 165. For example, the gate dielectric layers 162 may be disposed to surround the entirety of surfaces other than an uppermost surface of the gate electrode 165. The gate dielectric layers 162 may be in contact with internal spacers 150 below the plurality of channel layers 141, 142, 143, and 144, and may be spaced apart from the source/drain regions 130 by the internal spacers 150. The gate dielectric layers 162 may extend between the gate electrode 165 and the gate spacer layers 164, but an example embodiment thereof is not limited thereto. The gate dielectric layers 162 may include oxide, nitride, or a high-k (high-K) material. The high-K material may be a dielectric material having a dielectric constant higher than that of silicon oxide (SiO₂). The high-K material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In example embodiments, the gate dielectric layers 162 may be formed as multilayer films.

The gate electrode 165 may fill a space between the first to fourth channel layers 141, 142, 143, and 144 on the active region 105 and may extend to the channel structure 140. The gate electrode 165 may be spaced apart from the first to fourth channel layers 141, 142, 143, and 144 by the gate dielectric layers 162. The gate electrode 165 may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In example embodiments, the gate electrode 165 may include two or more multilayers.

The gate spacer layers 164 may be disposed on opposing side surfaces of the gate electrode 165 on the channel structure 140. For example, the gate spacer layers 164 may be disposed on opposing side surfaces of the fifth gate portion 160p5. The gate spacer layers 164 may insulate the source/drain regions 130 and the gate electrode 165. In example embodiments, the gate spacer layers 164 may be formed in a multilayer structure. In some examples, the gate spacer layers 164 may be formed of oxide, nitride, or oxynitride, and may be formed of, for example, a low-K film.

The gate capping layer 167 may be disposed on the gate electrode 165 and the gate spacer layers 164. An upper surface of the gate capping layer 167 may be coplanar with an upper surface of the interlayer insulating layer 170. In some example embodiments, a lower surface of the gate capping layer 167 may have a downwardly curved shape. The gate capping layer 167 may include an insulating material, for example, oxide, nitride, or oxynitride.

The source/drain regions 130 may have portions disposed in recess regions of the active region 105. The source/drain regions 130 may be partially recessed into an upper portion of the active region 105 on both sides of the gate structure 160. The recess regions may extend along side surfaces of the channel structures 140 and side surfaces of the gate dielectric layers 162. The source/drain regions 130 on opposing sides of the gate structure 160 may be spaced apart from each other in a first direction (e.g., in the X-direction), and may be referred to as a first source/drain region 130a and a second source/drain region 130b, respectively. The source/drain regions 130 may be disposed to cover side surfaces in the X-direction of each of the first to fourth channel layers 141, 142, 143, and 144 of the channel structures 140. The upper surfaces of the source/drain regions 130 may be positioned at a level equal to or higher than a level of a lower surface of the gate electrodes 165 on the channel structures 140, and the level may be varied in example embodiments. The side surfaces of the source/drain regions 130 may have an unevenness (e.g., may not be planar) along the first to fourth channel layers 141, 142, 143, and 144 and the internal spacers 150. The side surfaces of the source/drain regions 130 may protrude toward the gate structure 160 between the plurality of channel layers 141, 142, 143, and 144.

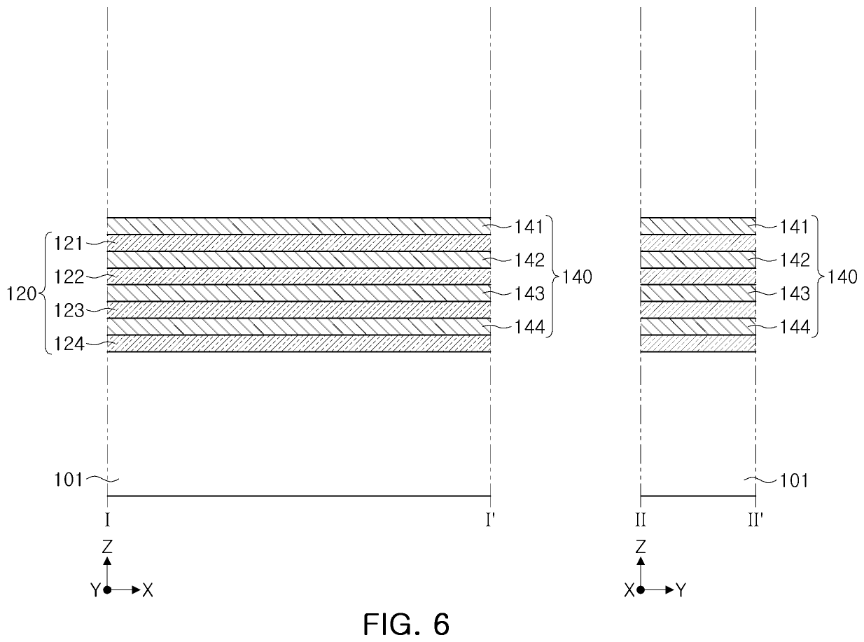

The source/drain regions 130 may include first to fourth protrusions 130p1, 130p2, 130p3, and 130p4 protruding toward the gate structure 160 from below the plurality of channel layers 141, 142, 143, and 144, respectively. The first to fourth protrusions 130p1, 130p2, 130p3, and 130p4 may be components formed in substantially the same shape or different shapes depending on a concentration of the sacrificial layers 120 (see FIG. 6) stacked at the corresponding positions. The first protrusion 130p1 may be positioned between the first channel layer 141 and the second channel layer 142, and may beat the same level as the first gate portion 160p1. The second protrusion 130p2 may be positioned between the second channel layer 142 and the third channel layer 143 and may be at the same level as the second gate portion 160p2. The third protrusion 130p3 may be positioned between the third channel layer 143 and the fourth channel layer 144 and may beat the same level as the third gate portion 160p3. The fourth protrusion 130p4 may be positioned between the fourth channel layer 144 and the active region 105 and may beat the same level as the fourth gate portion 160p4. The first protrusion 130p1 may be referred to as an uppermost protrusion, and the fourth protrusion 130p4 may be referred to as a lowermost protrusion. In some example embodiments, when a single channel structure 140 includes three channel layers, the third protrusion 130p3 may be referred to as a lowermost protrusion.

The first protrusion 130p1 may have a first protruding length P1, the second protrusion 130p2 may have a second protruding length P2, the third protrusion 130p3 may have a third protruding length P3, and the fourth protrusion 130p4 may have a fourth protruding length P4. The first to fourth protruding lengths P1, P2, P3, and P4 may be the same value, substantially the same value, or different values. The first protruding length P1 and the fourth protruding length P4 may be greater than the second protruding length P2 and the third protruding length P3. In some example embodiments, the first protruding length P1 and the fourth protruding length P4 may be the same or substantially the same, and the second protruding length P2 and the third protruding length P3 may be the same or substantially the same.

A spacing between the first and second source/drain regions 130 disposed on both sides of the gate structure 160 may be varied depending on the level depending on the first to fourth protruding lengths P1, P2, P3, and P4. The distance at which the first protrusions 130p1 of each of the first and second source/drain regions 130 are spaced apart from each other may be a first distance D1, the distance at which the second protrusions 130p2 are spaced apart from each other may be the second distance D2, the distance at which the third protrusions 130p3 are spaced apart from each other may be the third distance D3, and the distance at which the fourth protrusions 130p4 are spaced apart from each other may be the fourth distance D4. When the internal spacers 150 are disposed between the first to fourth protrusions 130p1, 130p2, 130p3, and 130p4 and the first to fourth gate portions 160p1, 160p2, 160p3, and 160p4, respectively, the first to fourth distances D1, D2, D3, and D4 may be greater than the first to fourth gate widths G1, G2, G3, and G4, respectively. In some example embodiments, when the internal spacers 150 are not present, the first to fourth distances D1, D2, D3, and D4 may be the same as or substantially the same as the first to fourth gate widths G1, G2, G3, and G4, respectively. The first distance D1 and the fourth distance D4 may be less than the second distance D2 and the third distance D3. In some example embodiments, the first distance D1 and the fourth distance D4 may be the same or substantially the same, and the second distance D2 and the third distance D3 may be the same or substantially the same.

The specific shapes of the side surfaces of the source/drain regions 130 may be varied in example embodiments. The source/drain regions 130 may be epitaxially grown regions and may include a plurality of epitaxial layers. The epitaxially grown surfaces of the source/drain regions 130 may be in contact with the channel structures 140, the internal spacers 150, and the interlayer insulating layer 170.

The source/drain regions 130 may include a semiconductor material, for example, silicon (Si) or germanium (Ge), and may further include dopants. For example, when the semiconductor device 100A is implemented as an nFET, the dopants may be phosphorus (P), arsenic (As), or antimony (Sb). For example, when the semiconductor device 100A is a pFET, the dopants may be boron (B), gallium (Ga), and indium (In). In example embodiments, the source/drain regions 130 may be configured as the plurality of epitaxial layers.

In example embodiments, source/drain regions 130 including uppermost protrusion 130p1 and lowermost protrusion 130p4 having relatively large protruding lengths may be included, and accordingly, the first distance D1 between the uppermost protrusions 130p1 and the fourth distance D4 between the lowermost protrusions 130p4 may be formed to be relatively small. Due to the shape of the source/drain regions 130, a first gate width G1 of the first gate portion 160p1 and a fourth gate width G4 of the fourth gate portion 160p4 may have widths less than widths of a second gate width G2 of the second gate portion 160p2 and a third gate width G3 of the third gate portion 160p3. By forming the protruding length of the lowermost protrusion 130p4 to be relatively large, a region in which the lowermost protrusion 130p4 overlaps the gate structure 160 may increase, and reliability of a process may be improved. By forming the protruding length of the uppermost protrusion 130p1 to be relatively large, the region in which the uppermost protrusion 130p1 overlaps the gate structure 160 may increase, and the space of the contact plug 180, especially the metal-semiconductor compound layer 181, may be sufficiently ensured. The second gate width G2 and the third gate width G3 may be formed to be relatively large, such that electrical properties of the corresponding portions may be improved. By including the source/drain regions 130 and the gate structures 160, a semiconductor device having improved reliability and electrical properties may be provided. The effects of example embodiments related to the manufacturing method are described later in the description related thereto.

The interlayer insulating layer 170 may be disposed on the device isolation layer 110 to cover the upper surfaces of the source/drain region 130 and the device isolation layer 110. The interlayer insulating layer 170 may include oxide, nitride, or oxynitride, for example, a low-K material. In example embodiments, the interlayer insulating layer 170 may include a plurality of insulating layers.

The internal spacers 150 may be disposed between the gate structure 160 and the source/drain region 130 below the plurality of channel layers 141, 142, 143, and 144 on the active region 105, respectively. The internal spacers 150 may be disposed to extend in the third direction (e.g., the Z-direction) between the first to fourth channel layers 141, 142, 143, and 144, and parallel to the gate electrode 165. The internal spacers 150 may cover side surfaces of the gate structure 160 along the X-direction below the channel structure 140. Below the first channel layer 141, the gate structure 160 and the source/drain region 130 may be spaced apart from each other by the internal spacers 150. The internal spacers 150 may include an insulating material, for example, oxide, nitride, or oxynitride.

The contact plug 180 may be disposed on the source/drain region 130. The contact plug 180 may be connected to the source/drain region 130 and may transmit an electrical signal to the source/drain region 130. The contact plug 180 may be recessed into the source/drain regions 130 and may extend into the source/drain region 130. The contact plug 180 may have an inclined side surface such that a width thereof may decrease toward the substrate 101 and the inclined surface may be defined according to an aspect ratio, but an example embodiment thereof is not limited thereto. The contact plug 180 may extend downwardly below a lower surface of a first channel layer 141, which is a first channel layer, of the channel structure 140 as in the example embodiment, and in example embodiments, the contact plug 180 may extend below a lower surface of the second channel layer 142 or the third channel layer 143. For example, the lower end of the contact plug 180 may be disposed at a level lower than a level of the first protrusion 130p1, that is, the uppermost protrusion 130p1.

The contact plug 180 may include a metal-semiconductor compound layer 181 and a contact conductive layer 183. The metal-semiconductor compound layer 181 may be in contact with the source/drain region 130. The metal-semiconductor compound layer 181 may be disposed along a recessed surface of the source/drain region 130. An upper end of the metal-semiconductor compound layer 181 may be positioned at a level equal to or higher than a level of an upper surface of the first channel layer 141. The upper end of the metal-semiconductor compound layer 181 may be positioned at a level equal to or higher than a level of an upper surface of the source/drain region 130. A lower end of the metal-semiconductor compound layer 181 may be disposed at a level lower than a level of the first protrusion 130p1, which may be the uppermost protrusion 130p1. The metal-semiconductor compound layer 181 may include a metal element and a semiconductor element, and may include, for example, TiSi, CoSi, MoSi, LaSi, NiSi, TaSi, or Wsi. Alternatively, the metal-semiconductor compound layer 181 may include germanium (Ge) in addition to or instead of silicon (Si) in the materials. The contact conductive layer 183 may be disposed on the metal-semiconductor compound layer 181. The contact conductive layer 183 may include a metal material such as, for example, tungsten (W), cobalt (Co), molybdenum (Mo), copper (Cu), ruthenium (Ru), or aluminum (Al).

A gate contact plug and an interconnection structure such as the contact plug 180 may be disposed on the gate electrode 165, and an interconnection structure such as an interconnection line connected to the contact plug 180 may be disposed on the contact plug 180.

In the description of the example embodiments below, descriptions that would overlap with the descriptions of FIGS. 1 to 2B may be omitted with the understanding that the description of FIGS. 1 to 2B are applicable.

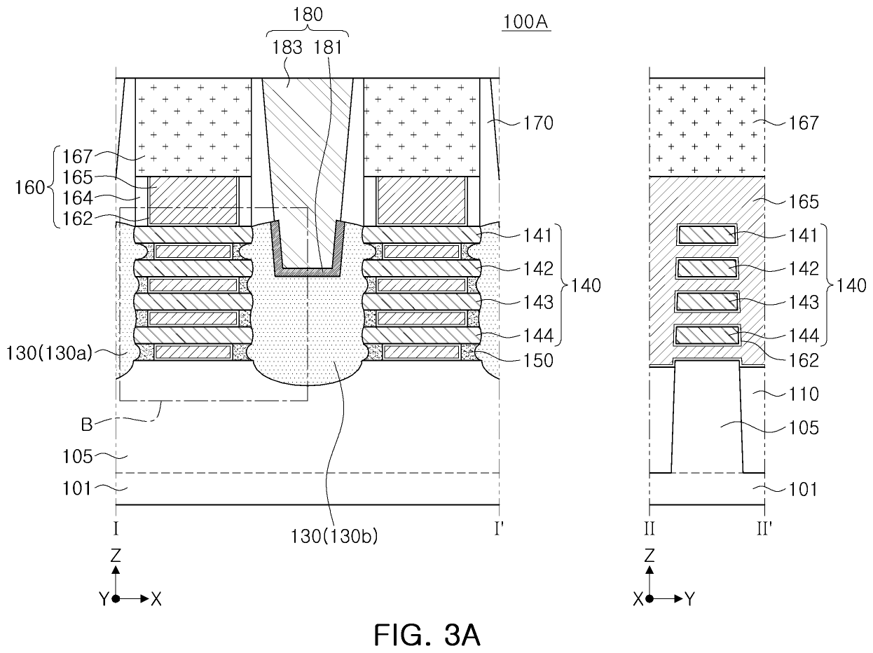

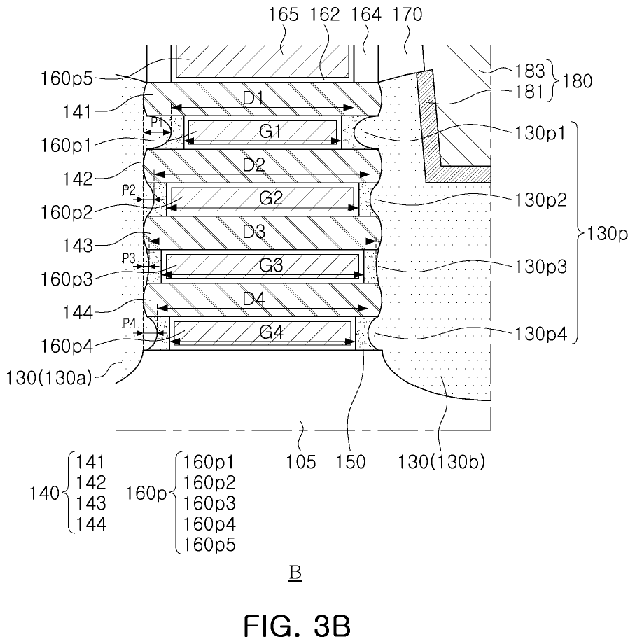

FIG. 3A is a cross-sectional diagram illustrating a portion of a semiconductor device according to example embodiments and illustrates regions corresponding to those shown in FIG. 2A.

FIG. 3B is an enlarged diagram illustrating a portion of a semiconductor device according to example embodiments, illustrating region “B” in FIG. 3A.

Referring to FIGS. 3A and 3B, unlike the semiconductor device 100 in FIGS. 1 to 2B, in the semiconductor device 100A, the first protruding length P1 of the first protrusion 130p1 of the source/drain region 130 may be greater than the fourth protruding length P4 of the fourth protrusion 130p4, and the second protruding length P2 of the second protrusion 130p2 may be greater than the third protruding length P3 of the third protrusion 130p3. For example, in ascending order, the lengths may be listed as the first protruding length P1, the fourth protruding length P4, the second protruding length P2, and the third protruding length P3. Accordingly, in decreasing order, the lengths may be listed as the first distance D1, the fourth distance D4, the second distance D2 and the third distance D3, and in decreasing order, the widths may be the first gate width G1, the fourth gate width G4, the second gate width G2 and the third gate width G3. The semiconductor device 100A may implement substantially the same as that of the semiconductor device 100 in FIGS. 1 to 2B in other aspects, and the difference in structural characteristics thereof may be due to characteristics of the manufacturing method. The related descriptions will be described later in the description referring to the manufacturing method.

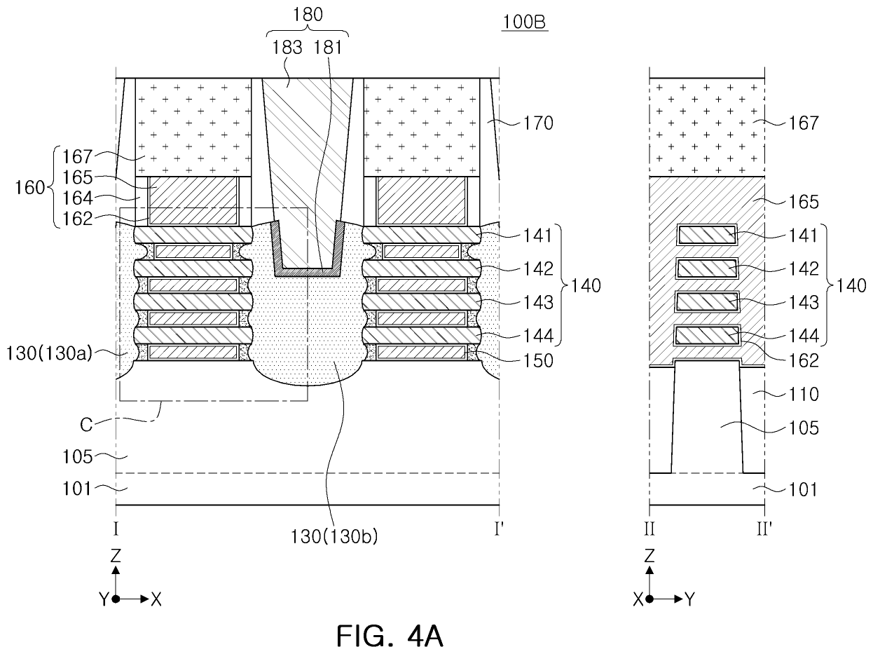

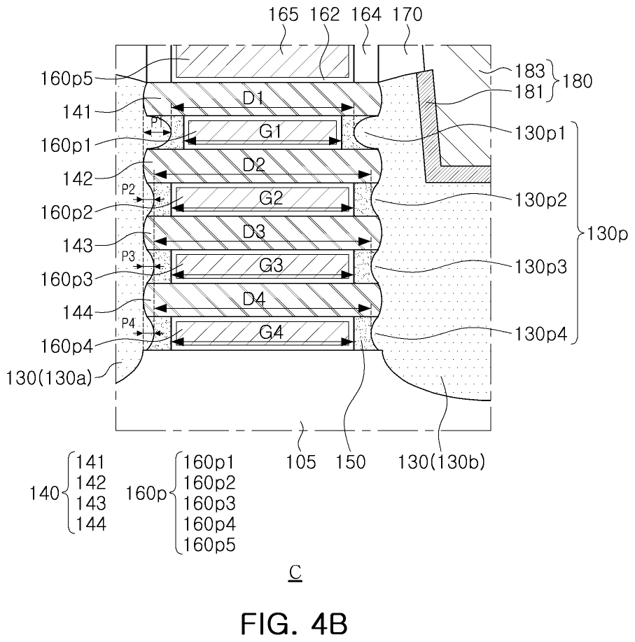

FIG. 4A illustrates cross-sectional diagrams of a portion of a semiconductor device according to example embodiments and illustrates regions corresponding to those shown in FIG. 2A.

FIG. 4B is an enlarged diagram illustrating a portion of a semiconductor device according to example embodiments, illustrating region “C” in FIG. 4A.

Referring to FIG. 4B, unlike the semiconductor device 100 in FIGS. 1 to 2B, in a semiconductor device 100B, the first protruding length P1 of the first protrusion 130p1 may be greater than the second protruding length P2 of the other second protrusion 130p2, the third protruding length P3 of the third protrusion 130p3, and the fourth protruding length P4 of the fourth protrusion 130p4, and the second to fourth protruding lengths P2, P3, and P4 may be substantially the same. Since the first protruding length P1 is formed relatively large, the first gate width G1 of the first gate portion 160p1 may be formed relatively small, and a space of the contact plug 180, particularly, the space of the metal-semiconductor compound layer 181 of the contact plug 180, may be ensured, and the contact plug 180 and the first gate portion 160p1 may be stably spaced apart from each other.

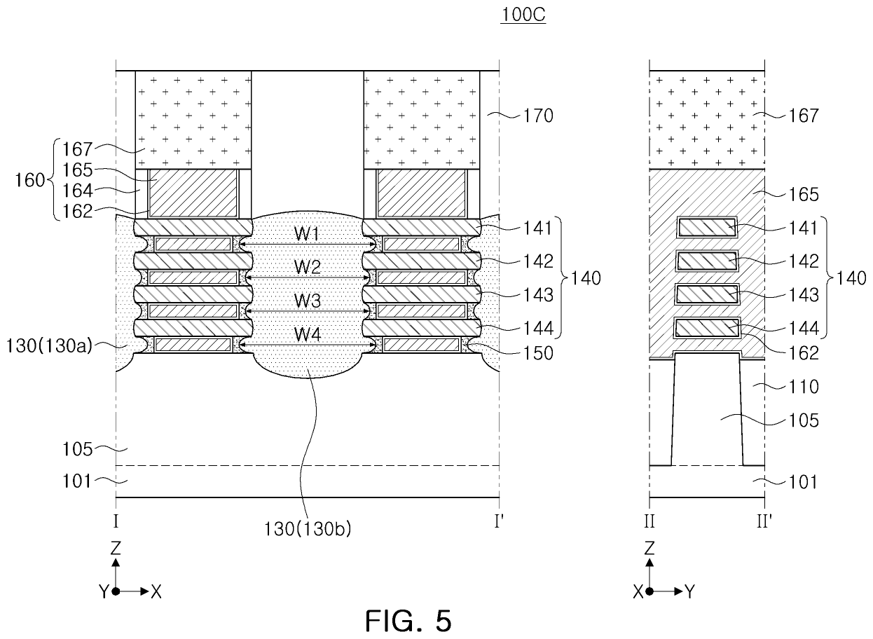

FIG. 5 is an illustration of cross-sectional diagrams of a portion of a semiconductor device according to example embodiments, and illustrates regions corresponding to those shown in FIG. 2A.

Referring to FIG. 5, a semiconductor device 100C may include a source/drain region 130 not connected to a contact plug, such as contact plug 180 of the semiconductor device 100 in FIGS. 1 to 2B. The source/drain region 130 may include first to fourth protrusions 130p1, 130p2, 130p3, and 130p4, such that the source/drain region 130 may have different widths in the first horizontal direction (e.g., X-direction) depending on a level. A level portion including the first protrusion 130p1 may have a first width W1, a level portion including the second protrusion 130p2 may have a second width W2, a level portion including the third protrusion 130p3 may have a third width W3, and a level portion including the fourth protrusion 130p4 may have a fourth width W4. The first to fourth widths W1, W2, W3, and W4 may be maximum widths in different level portions. The first width W1 and the fourth width W4 may be greater than the second width W2 and the third width W3. In some example embodiments, the first width W1 and the fourth width W4 may be substantially the same, and the second width W2 and the third width W3 may be substantially the same. The first to fourth widths W1, W2, W3, and W4 may have different values depending on the shapes of the first to fourth protrusions 130p1, 130p2, 130p3, and 130p4, respectively, and the description of the first to fourth widths W1, W2, W3, and W4 may be applied in an example embodiment described with reference to another drawing depending on the features of the example embodiment. For example, in the case of the semiconductor device 100A in FIGS. 3A and 3B, or the semiconductor device 100B in FIGS. 4A and 4B, the first width W1 may be a maximum width of the source/drain region 130.

FIGS. 6, 7, 8, 9A, 10A, 11, 12, 13A, and 14A are cross-sectional diagrams illustrating a method of manufacturing a semiconductor device according to example embodiments, illustrating regions corresponding to those shown in FIG. 2A.

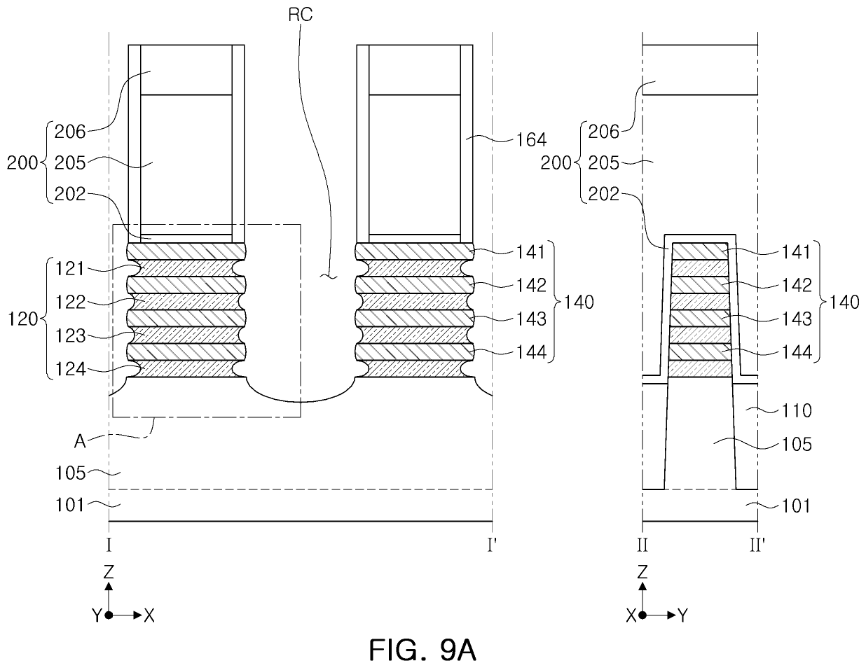

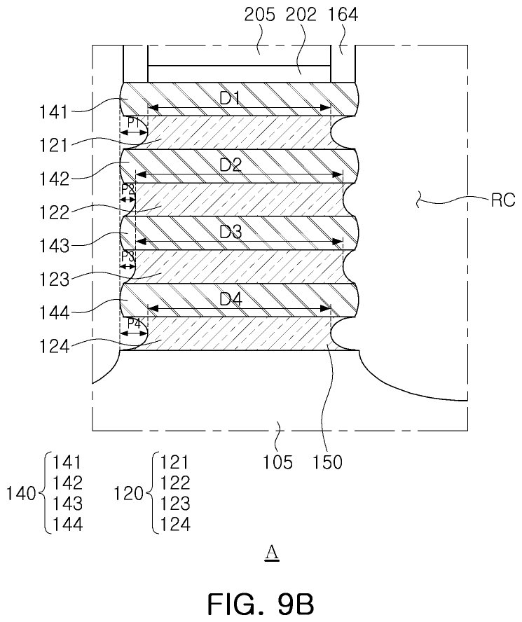

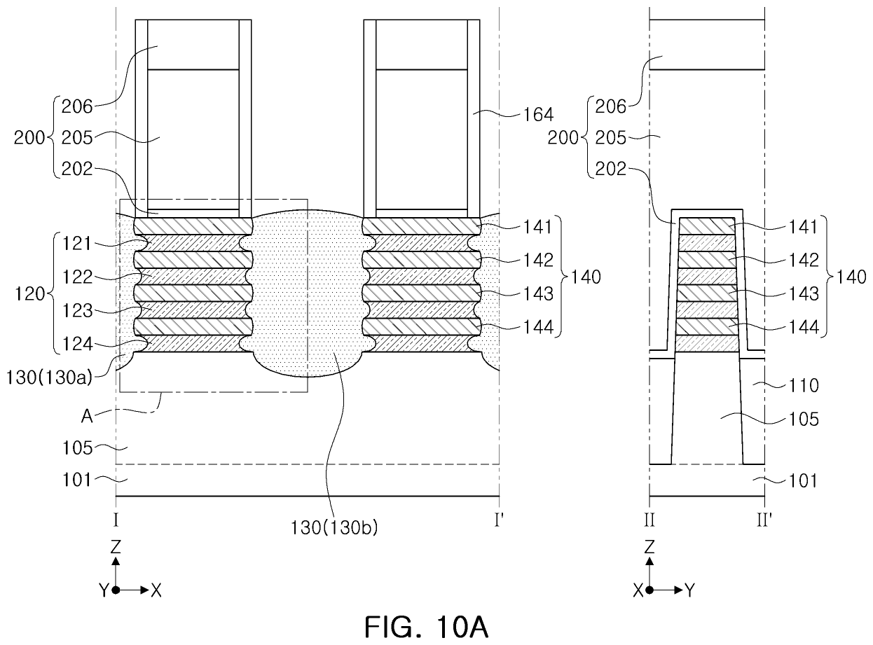

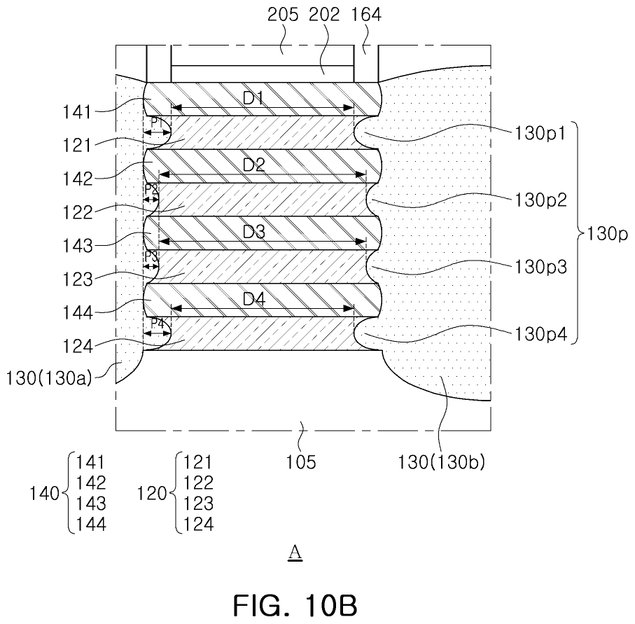

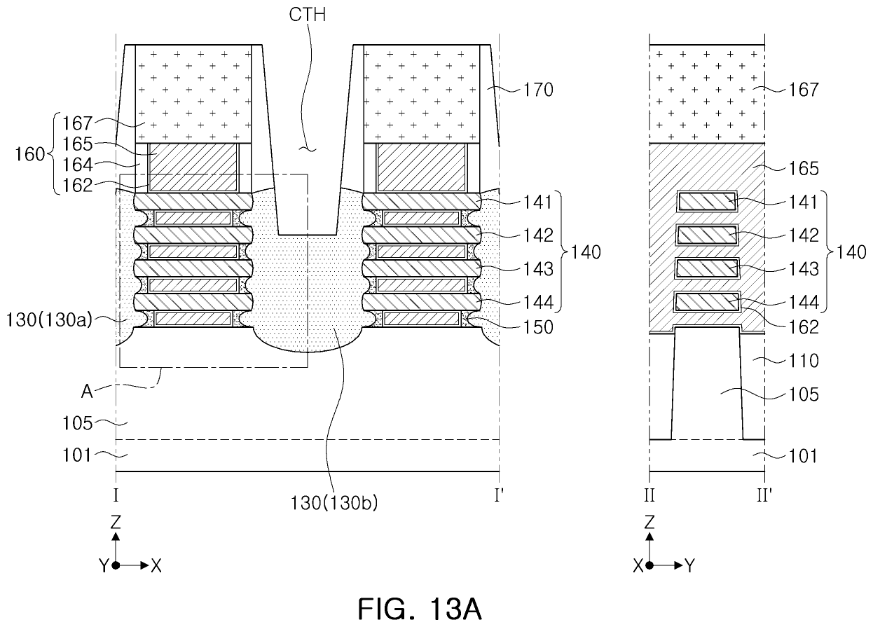

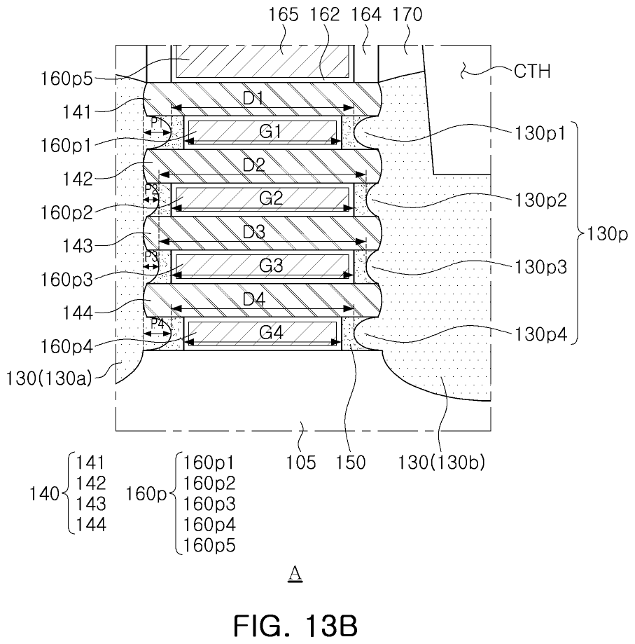

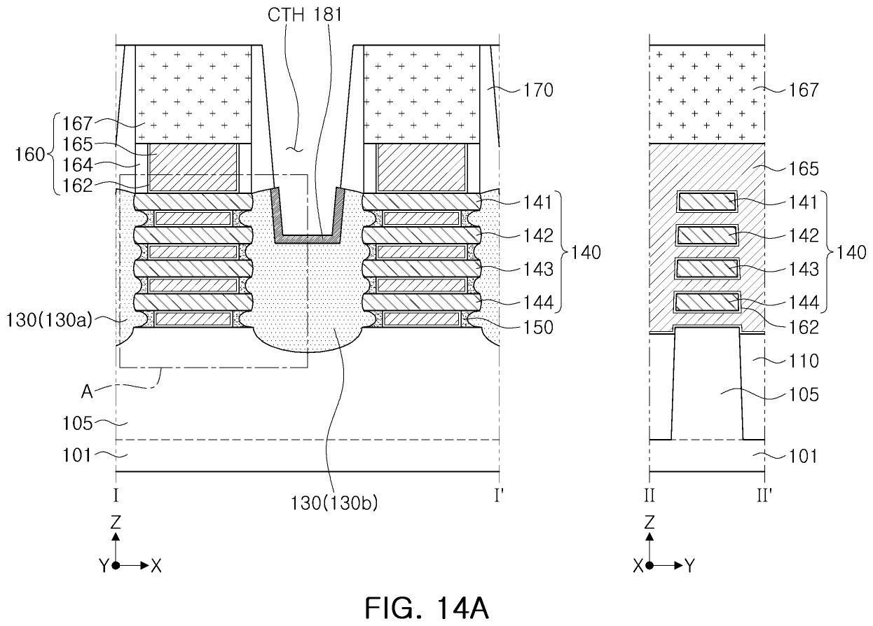

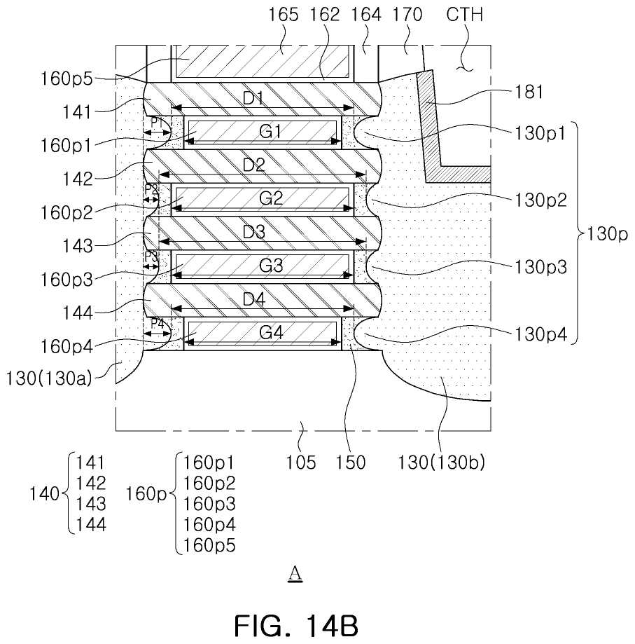

FIGS. 9B, 10B, 13B, and 14B are enlarged diagrams illustrating processes of a method of manufacturing a semiconductor device in order according to example embodiments. FIG. 9B is an enlarged diagram illustrating region “A” in FIG. 9A, FIG. 10B is an enlarged diagram illustrating region “A” in FIG. 10A, FIG. 13B is an enlarged diagram illustrating region “A” in FIG. 13A, and FIG. 14B is an enlarged diagram illustrating region “A” in FIG. 14A.

Referring to FIG. 6, a plurality of sacrificial layers 120 and a plurality of channel layers 141, 142, 143, and 144 may be alternately stacked on a substrate 101.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The plurality of channel layers 141, 142, 143, and 144 may include first to fourth channel layers 141, 142, 143, and 144, and the plurality of sacrificial layers 120 may include first to fourth sacrificial layers 121, 122, 123, and 124. The plurality of sacrificial layers 120 may be replaced with the gate dielectric layers 162 and the gate electrodes 165 below the first channel layer 141 through a subsequent process as illustrated in FIGS. 2A and 2B. The first sacrificial layer 121 may be replaced with the first gate portion 160p1, the second sacrificial layer 122 may be replaced with the second gate portion 160p2, the third sacrificial layer 123 may be replaced with the third gate portion 160p3, and the fourth sacrificial layer 124 may be replaced with the fourth gate portion 160p4. The plurality of sacrificial layers 120 may be formed of materials having etch selectivity with respect to the first to fourth channel layers 141, 142, 143, and 144, respectively. The first to fourth channel layers 141, 142, 143, and 144 may include materials different from materials of the first to fourth sacrificial layers 121, 122, 123, and 124. The first to fourth sacrificial layers 121, 122, 123, and 124 and the first to fourth channel layers 141, 142, 143, and 144 include a semiconductor material, for example, silicon (Si), silicon germanium (SiGe), or germanium (Ge), and may include different materials and may or may not include impurities. For example, the first to fourth sacrificial layers 121, 122, 123, and 124 may include silicon germanium (SiGe), and the first to fourth channel layers 141, 142, 143, and 144 may include silicon (Si). Concentrations of silicon (Si) and germanium (Ge) which the first to fourth sacrificial layers 121, 122, 123, and 124 may include may be the same or different. In some example embodiments, the concentration of germanium (Ge) in the first sacrificial layer 121 and the fourth sacrificial layer 124 may be greater than the concentration of germanium (Ge) in the second sacrificial layer 122 and the third sacrificial layer 123, and in such examples, the semiconductor device 100 in FIGS. 1 to 2B, the semiconductor device 100A shown in FIGS. 3A and 3B, or the semiconductor device 100C in FIGS. 5A and 5B may be manufactured according to a subsequent process. In such examples, the concentration of germanium (Ge) in the first sacrificial layer 121 and the concentration of germanium (Ge) in the fourth sacrificial layer 124 may be substantially the same, and the concentration of germanium (Ge) in the second sacrificial layer 122 and the concentration of germanium (Ge) in the third sacrificial layer 123 may be substantially the same. In some example embodiments, the concentration of germanium (Ge) in the first sacrificial layer 121 may be greater than the concentrations of germanium (Ge) in the second to fourth sacrificial layers 122, 123, and 124, and in this example, the semiconductor device 100B shown in FIGS. 4A and 4B may be manufactured by a subsequent process. In this case, the concentrations of germanium (Ge) in the second to fourth sacrificial layers 122, 123, and 124 may be substantially the same. In some example embodiments, the concentrations of germanium (Ge) in the first sacrificial layer 121 and the fourth sacrificial layer 124 may be 30 at % to 35 at %, and the concentrations of germanium (Ge) in the second sacrificial layer 122 and the third sacrificial layer 123 may be 25 at % to 30 at %. In some example embodiments, the concentrations of germanium (Ge) in the second sacrificial layer 122 and the third sacrificial layer 123 may be 32 at % to 33 at %, and the concentrations of germanium in the first sacrificial layer 121 and the fourth sacrificial layer 124 may be 33 at % to 40 at %.

A plurality of sacrificial layers 120 and first to fourth channel layers 141, 142, 143, and 144 may be formed by performing an epitaxial growth process from the stack structure. The number of channel layers stacked alternately with the sacrificial layers 120 may be varied in example embodiments.

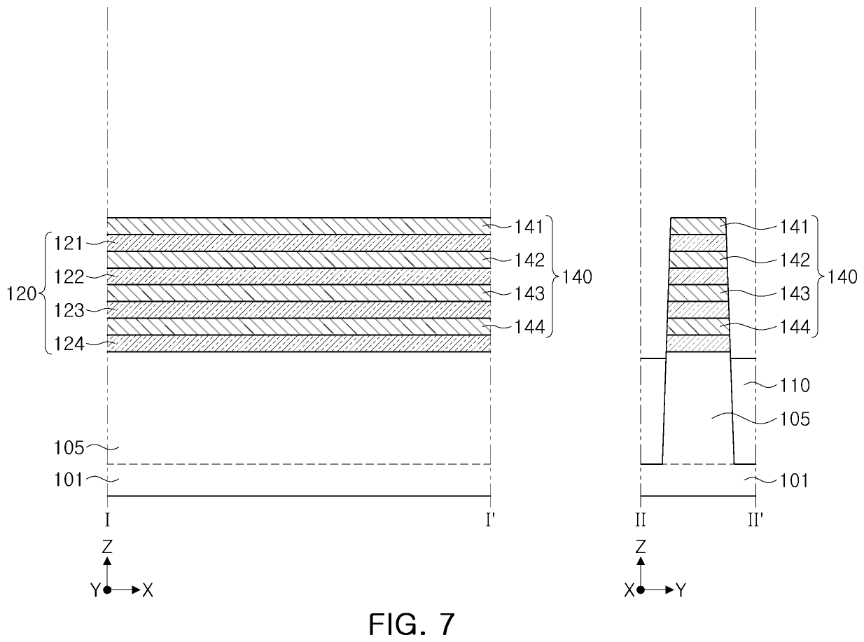

Referring to FIG. 7, by partially removing the plurality of sacrificial layers 120, the first to fourth channel layers 141, 142, 143, and 144, and the substrate 101, an active structure including an active region 105 may be formed, and a device isolation layer 110 may be formed.

The active structure may include the active region 105, the plurality of sacrificial layers 120, and the first to fourth channel layers 141, 142, 143, and 144. The active structure may be formed in a line shape extending lengthwise in one direction, for example, in the X-direction, and may be spaced apart from an active structure adjacent thereto in the Y-direction. Side surfaces of the active structure in the Y-direction may be coplanar with each other, and may be positioned linearly.

An insulating material may be filled in the region from which a portion of each of the active region 105, the plurality of sacrificial layers 120, and the first to fourth channel layers 141, 142, 143, and 144 is removed, and the insulating material may be partially removed, such that the device isolation layer 110 may be formed. An upper surface of the device isolation layer 110 may be formed to be lower than an upper surface of the active region 105.

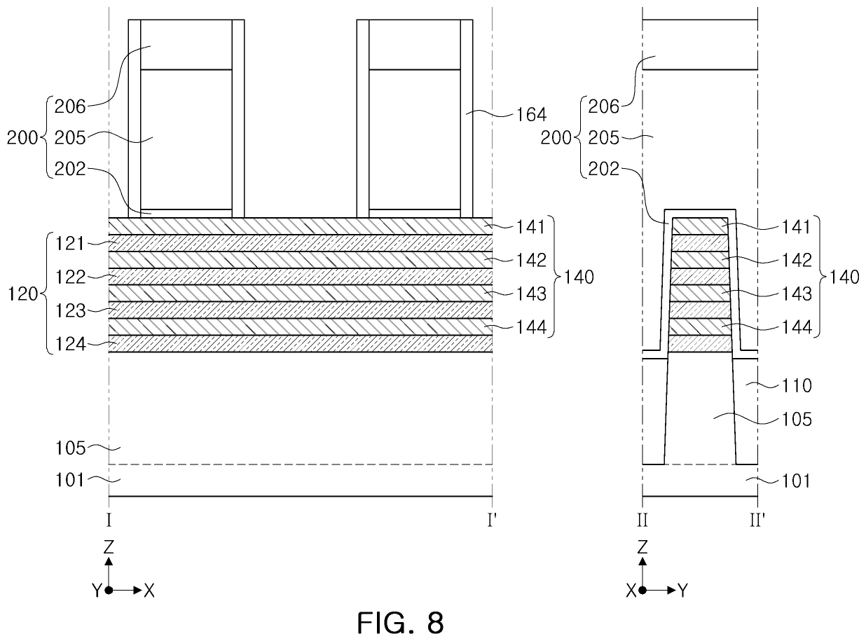

Referring to FIG. 8, sacrificial gate structures 200 and gate spacer layers 164 may be formed on the active structure.

Each of the sacrificial gate structures 200 may be a sacrificial structure formed in a region in which the gate dielectric layers 162 and the gate electrode 165 are disposed on the channel structure 140 through a subsequent process as illustrated in FIG. 5. The sacrificial gate structures 200 may have a line shape extending lengthwise in one direction intersecting the active structure. The sacrificial gate structures 200 may extend, for example, in the Y-direction. Each of the sacrificial gate structures 200 may include first and second sacrificial gate layers 202 and 205 and a mask pattern layer 206 stacked in order. The first and second sacrificial gate layers 202 and 205 may be patterned using the mask pattern layer 206.

The first and second sacrificial gate layers 202 and 205 may be an insulating layer and a conductive layer, respectively, but an example embodiment thereof is not limited thereto, and the first and second sacrificial gate layers 202 and 205 may be formed as an integrated layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on both side walls of the sacrificial gate structures 200. The gate spacer layers 164 may be formed of a low-K material, and may include SiO, SiN, SiCN, SiOC, SiON, or SiOCN, for example.

Referring to FIGS. 9A and 9B, by performing an etching process using the sacrificial gate structures 200 as an etching mask, recess regions RC penetrating the active structure and exposing the active region 105 may be formed.

Recess regions may be formed by removing a portion of the sacrificial layers 120 and the first to fourth channel layers 141, 142, 143, and 144 exposed from the sacrificial gate structures 200, and the plurality of sacrificial layers 120 may be partially removed. Accordingly, the first to fourth channel layers 141, 142, 143, and 144 may form channel structures 140 having a limited length in the X-direction.

A region of the plurality of sacrificial layers 120, exposed from the sacrificial gate structures 200, and a region overlapping the sacrificial gate structures 200 may be partially etched. The plurality of sacrificial layers 120 may include silicon germanium (SiGe) having the same or different compositions, and accordingly, the degree of removal in this process may be the same or different. For example, the concentration of germanium (Ge) in the first sacrificial layer 121 and the fourth sacrificial layer 124 may be greater than the concentration of germanium (Ge) in the second sacrificial layer 122 and the third sacrificial layer 123, and a relatively greater amount may be etched. The concentrations of germanium (Ge) in the first sacrificial layer 121 and the fourth sacrificial layer 124 may be substantially the same, and the extents of etching in this process may be substantially the same. The concentrations of germanium (Ge) in the second sacrificial layer 122 and the third sacrificial layer 123 may be substantially the same, and the extent of etching in this process may be substantially the same. In some example embodiments, even when a portion of the plurality of sacrificial layers 120 have the same concentration of germanium (Ge), the extents of etching in this process may decrease as the layers are disposed at lower levels. For example, even when the concentrations of germanium (Ge) of the first sacrificial layer 121 and the fourth sacrificial layer 124 are the same, the fourth sacrificial layer 124 positioned at a lower level may be relatively less etched. Similarly, even when the concentrations of germanium (Ge) of the second sacrificial layer 122 and the third sacrificial layer 123 are the same, the third sacrificial layer 123 positioned at a lower level may be relatively less etched. The amounts and shapes of etching of the first to fourth sacrificial layers 121, 122, 123, and 124 may be varied in this process depending on the concentrations of germanium (Ge) included therein, the level at which it is positioned, or the like, and various shapes of semiconductor devices may be manufactured as well as the semiconductor devices in FIGS. 1 to 5B depending on the subsequent process.

Referring to FIG. 10A and FIG. 10B, a plurality of source/drain regions 130 may be formed in the recess regions RC.

The source/drain regions 130 may be formed in the recess regions RC and may be formed by growing from side surfaces of the active regions 105 and channel structures 140, for example, by a selective epitaxial process. Depending on the degree and the shape of etching of the first to fourth sacrificial layers 121, 122, 123, and 124, the source/drain regions 130 may be formed to have first to fourth protrusions 130p1, 130p2, 130p3, and 130p4.

The source/drain regions 130 may include a plurality of epitaxial layers, and the epitaxial layers may have different non-silicon concentrations. The source/drain regions 130 may include impurities by in-situ doping, and may include a plurality of layers having different doping elements and/or doping concentrations. In some example embodiments, the source/drain regions 130 may have N-type conductivity and may be formed to include at least one dopant of boron (B), gallium (Ga), or indium (In). In some example embodiments, the source/drain regions 130 may have P-type conductivity and may be formed to include at least one dopant of boron (B), gallium (Ga), or indium (In).

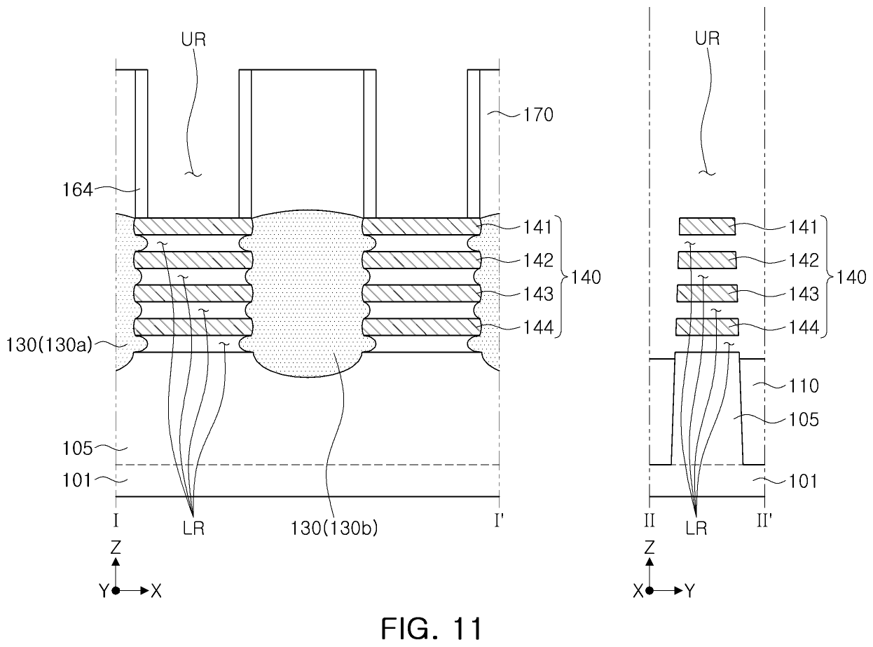

Referring to FIG. 11, an interlayer insulating layer 170 may be partially formed, and the sacrificial gate structures 200 and the plurality of sacrificial layers 120 may be removed.

The interlayer insulating layer 170 may be formed by forming an insulating film covering the sacrificial gate structures 200 and the source/drain regions 130 and performing a planarization process.

The sacrificial gate structures 200 and the plurality of sacrificial layers 120 may be selectively removed with respect to the gate spacer layers 164 and the channel structures 140. First, an upper gap regions UR may be formed by removing the sacrificial gate structures 200, and a lower gap regions LR may be formed by removing the sacrificial layers 120 exposed through the upper gap regions UR. For example, when the plurality of sacrificial layers 120 include silicon germanium (SiGe) and the channel structures 140 include silicon (Si), the plurality of sacrificial layers 120 may be selectively removed with respect to the channel structures 140 by performing a wet etching process.

Since the source/drain regions 130 include a lowermost protrusion 130p4 having a relatively large protruding length, the lower gap region LR may be prevented from being formed in the internal region of the source/drain regions 130 during the process of removing the fourth sacrificial layer 124.

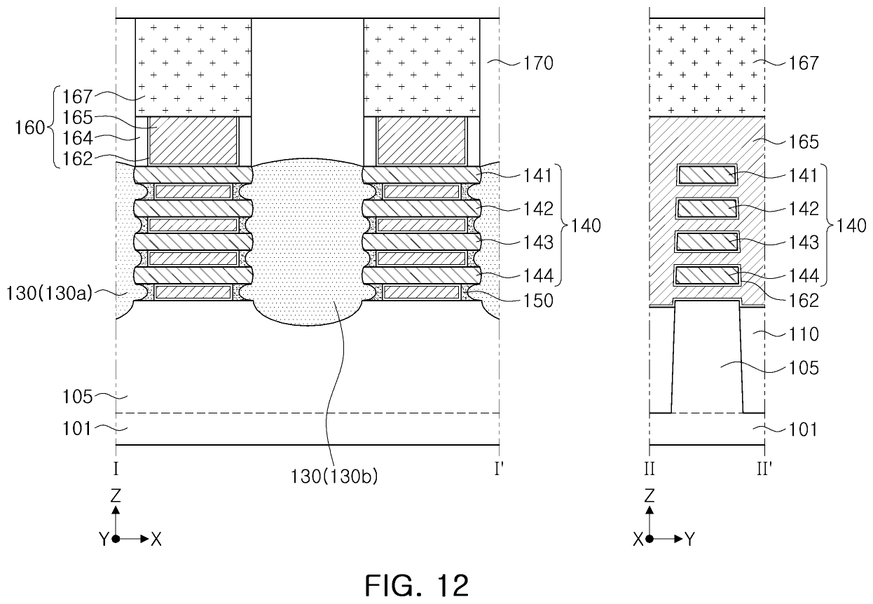

Referring to FIG. 12, the internal spacers 150 may be formed, and the gate dielectric layers 162, the gate electrode 165, and the gate capping layer 167 may be formed, thereby forming the gate structures 160.

The internal spacers 150 may be formed to cover the plurality of protrusions 130p1, 130p2, 130p3, and 130p4 of the source/drain regions 130 in the lower gap regions LR by depositing an insulating material in the lower gap regions LR, and partially etching the plurality of channel layers 141, 142, 143, and 144 to expose the lower gap regions LR.

The gate structures 160 may be formed to fill the upper gap regions UR and the lower gap regions LR. The portions filling the lower gap regions LR may be included in the first to fourth gate portions 160p1, 160p2, 160p3, and 160p4, and the first to fourth gate widths G1, G2, G3, and G4 thereof may be formed substantially the same or different from each other by the first to fourth protrusions 130p1, 130p2, 130p3, and 130p4 and the internal spacers 150. The gate dielectric layers 162 may be formed to conformally cover internal surfaces of the upper gap regions UR and the lower gap regions LR. The gate electrode 165 may be formed to completely fill the upper gap regions UR and the lower gap regions LR, and may be removed downwardly from the upper gap regions UR to a predetermined depth together with the gate dielectric layers 162 and the gate spacer layers 164. Accordingly, the gate structures 160 including the gate dielectric layers 162, the gate electrodes 165, and the gate spacer layers 164 may be formed.

Referring to FIGS. 13A and 13B, contact holes CTH penetrating the interlayer insulating layer 170 and extending into the source/drain regions 130 may be formed.

The contact holes CTH may be formed by etching the interlayer insulating layer 170 downwardly in the region in which the contact plugs 180 (see FIG. 2a) are formed, and recessing the exposed source/drain regions 130 from the upper surface. A lower end of the contact hole CTH may be formed at a level lower than a level of a lower surface of the first channel layer 141, and in example embodiments, the end may be formed at a level lower than a level of the lower surface of the first gate portion 160p1.

Referring to FIG. 14A and FIG. 14B, a metal-semiconductor compound layer 181 may be formed on the source/drain region 130 exposed by the contact hole CTH.

The metal-semiconductor compound layer 181 may be formed by depositing a metal layer at a relatively high temperature, for example, about 400° C. to about 500° C., and allowing the metal layer to react with the source/drain regions 130. The metal-semiconductor compound layer 181 may be formed to include a portion of the materials of the source/drain region 130 exposed by the contact hole CTH, and may extend by centering on boundaries of the contact hole CTH. Since the first protruding length P1 of the uppermost protrusion 130p1 is formed relatively large, the space of the metal-semiconductor compound layer 181 may be stably ensured.

Thereafter, referring to FIGS. 2A and 2B together, a contact conductive layer 183 may be formed to fill the contact hole CTH on a metal-semiconductor compound layer 181, and a contact plug 180 may be formed. Accordingly, the semiconductor device 100 in FIGS. 1 to 2B may be manufactured.

According to the aforementioned example embodiments, by including protrusions in upper and lower portions of the source/drain connected to the plurality of channel layers, a semiconductor device having improved reliability may be provided.

While the example embodiments have been illustrated and described above, it will be apparent to those skilled in the art that modifications and variations could be made without departing from the scope of the inventive concept as defined by the appended claims.

What is claimed is:

1. A semiconductor device, comprising:
a gate structure extending in a first direction;
a first source/drain region on a first side of the gate structure and a second source/drain region on an opposing side of the gate structure, the first source/drain region and second source/drain region spaced apart from each other in a second direction perpendicular to the first direction;
a plurality of channel layers, each of the channel layers surrounded by the gate structure and located between the first and second source/drain regions and spaced apart from each other in a vertical direction, wherein the plurality of channel layers includes a lowermost channel layer, an uppermost channel layer, and a first intermediate channel layer between the lowermost channel layer and the lowermost channel layer; and
a contact plug electrically connected to the first source/drain region,
wherein each of the first source/drain region and the second source/drain region includes a plurality of protrusions including an uppermost protrusion connected to the uppermost channel layer below the uppermost channel layer and protruding in a direction toward the gate structure, a lowermost protrusion connected to the lowermost channel layer below the lowermost channel layer and protruding in the direction toward the gate structure, and a first intermediate protrusion connected to the first intermediate channel layer below the first intermediate channel layer and protruding in the direction toward the gate structure, and
wherein a distance between the uppermost protrusion of the first source/drain region and the uppermost protrusion of the second source/drain region in the second direction and a distance between the lowermost protrusion of the first source/drain region and a lowermost protrusion of the second source/drain region in the second direction are each less than a distance between the first intermediate protrusion of the first source/drain region and the first intermediate protrusion of the second source/drain region in the second direction.

2. The semiconductor device of claim 1, wherein the lowermost protrusion of each of the first source/drain region and the second source/drain region, the uppermost protrusion of each of the first source/drain region and the second source/drain region, and the first intermediate protrusion of each of the first source/drain region and the second source/drain region include a portion overlapping the gate structure in the vertical direction.

3. The semiconductor device of claim 1, wherein a distance between the uppermost protrusion of the first source/drain region and the uppermost protrusion of the second source/drain region is a minimum distance between the first source/drain region and the second source/drain region.

4. The semiconductor device of claim 1,
wherein the plurality of channel layers further includes a second intermediate channel layer between the first intermediate channel layer and the lowermost channel layer, and
wherein the plurality of protrusions of each of the first source/drain region and the second source/drain region further includes a second intermediate protrusion connected to the second intermediate channel layer below the second intermediate channel layer and protruding in the direction toward the gate structure.

5. The semiconductor device of claim 4,
wherein a distance between the uppermost protrusion of the first source/drain region and the uppermost protrusion of the second source/drain region is a first distance, wherein a distance between the first intermediate protrusion of the first source/drain region and the first intermediate protrusion of the second source/drain region is a second distance,
wherein a distance between the second intermediate protrusion of the first source/drain region and the second intermediate protrusion of the second source/drain region is a third distance, and
wherein a difference between the second distance and the third distance is less than a difference between the first distance and the second distance.

6. The semiconductor device of claim 4,
wherein a distance between the first intermediate protrusion of the first source/drain region and the first intermediate protrusion of the second source/drain region is a second distance,
wherein a distance between the second intermediate protrusion of the first source/drain region and the second intermediate protrusion of the second source/drain region is a third distance,
wherein a distance between the lowermost protrusion of the first source/drain region and the lowermost protrusion of the second source/drain region is a fourth distance, and
wherein a difference between the second distance and the third distance is less than a difference between the fourth distance and the third distance.

7. The semiconductor device of claim 4, wherein a first distance between the uppermost protrusion of the first source/drain region and the uppermost protrusion of the second source/drain region is less than a fourth distance between the lowermost protrusion of the first source/drain region and the lowermost protrusion of the second source/drain region.

8. The semiconductor device of claim 4, wherein a second distance between the first intermediate protrusion of the first source/drain region and the first intermediate protrusion of the second source/drain region is less than a third distance between the second intermediate protrusion of the first source/drain region and the second intermediate protrusion of the second source/drain region.

9. The semiconductor device of claim 1,
wherein the contact plug extends into a recess of the first source/drain region, and
wherein the contact plug includes a metal-semiconductor compound layer disposed along a recessed surface of the first source/drain region and a contact conductive layer on the metal-semiconductor compound layer.

10. The semiconductor device of claim 9, wherein a lower end of the metal-semiconductor compound layer is disposed at a level lower than a level of the uppermost protrusion.

11. A semiconductor device, comprising:
a gate structure extending lengthwise in a first direction;
a plurality of channel layers each of the channel layers surrounded by the gate structure, and the plurality of channel layers including an uppermost channel layer, a first intermediate channel layer, and a lowermost channel layer spaced apart from each other downwardly in order; and
a source/drain region on a side of the gate structure and connected to the plurality of channel layers,
wherein the source/drain region includes a plurality of protrusions including an uppermost protrusion protruding in a first horizontal direction toward the gate structure between the uppermost channel layer and the first intermediate channel layer, a first intermediate protrusion protruding in the first horizontal direction toward the gate structure between the first intermediate channel layer and the lowermost channel layer, and a lowermost protrusion protruding in the first horizontal direction toward the gate structure below the lowermost channel layer, and
wherein a first maximum width in the first horizontal direction of a first portion including the uppermost protrusion of the source/drain region and a second maximum width in the first horizontal direction of a second portion including the lowermost protrusion of the source/drain region are each greater than a third maximum width in the first horizontal direction of a third portion including the first intermediate protrusion of the source/drain region.

12. The semiconductor device of claim 11, wherein one of the first maximum width and the second maximum width is a horizontal maximum width of the source/drain region.

13. The semiconductor device of claim 11, further comprising:
a contact plug partially extending into a recess in an upper surface of the source/drain region and connected to the source/drain region,
wherein at least a portion of the uppermost protrusion overlaps the contact plug and at least a portion of the first intermediate protrusion does not overlap the contact plug, in a direction perpendicular to a side surface of the gate structure.

14. The semiconductor device of claim 11, wherein the first maximum width is greater than the second maximum width.

15. The semiconductor device of claim 11, further comprising:
internal spacers disposed between the respective protrusions in the source/drain region and the gate structure.

16. A semiconductor device, comprising:
a gate structure extending in a first direction;
a plurality of channel layers, each of the channel layers surrounded by the gate structure and including first, second, third, and fourth channel layers disposed downwardly in order;
a source/drain region on a side of the gate structure and connected to the plurality of channel layers; and
a contact plug electrically connected to the source/drain region,
wherein the gate structure includes a first gate portion positioned between the first channel layer and the second channel layer, a second gate portion positioned between the second channel layer and the third channel layer, a third gate portion positioned between the third channel layer and the fourth channel layer, and a fourth gate portion positioned below the fourth channel layer,
wherein a first gate width of the first gate portion is less than a second gate width of the second gate portion, and
wherein a fourth gate width of the fourth gate portion is less than a third gate width of the third gate portion.

17. The semiconductor device of claim 16, wherein a distance between a central axis of the source/drain region and the first gate portion is greater than a distance between a central axis of the source/drain region and the second gate portion.

18. The semiconductor device of claim 16, wherein the third gate width is larger than the second gate width, and the fourth gate width is larger than the first gate width.

19. The semiconductor device of claim 16,
wherein the source/drain region includes a first protrusion disposed at the same level as the first gate portion and protruding toward the first gate portion, a second protrusion disposed at the same level as the second gate portion and protruding toward the second gate portion, a third protrusion disposed at the same level as the third gate portion and protruding toward the third gate portion, and a fourth protrusion disposed at the same level as the fourth gate portion and protruding toward the fourth gate portion,
wherein a first protruding length of the first protrusion is greater than a second protruding length of the second protrusion, and
wherein a fourth protruding length of the fourth protrusion is greater than a third protruding length of the third protrusion.

20. The semiconductor device of claim 19,
wherein the first protruding length is greater than the fourth protruding length, and
wherein the second protruding length is greater than the third protruding length.
